(19) United States
(12) Patent Application Publication
(10) Pub. No.: US 2004/0190268 A1
(43) Pub. Date: Sep. 30, 2004

(54) Retention mechanism for high mass add-in cards

(76) Inventors: Yun Ling, Portland, OR (US); Thai Dan Tong, Beaverton, OR (US); Scott Noble, Beaverton, OR (US); Yinan Wu, Westborough, MA (US); Daniel S. Willis, Portland, OR (US); Brent A. Hill, Portland, OR (US); John M. Lynch, Forest Grove, OR (US); Guixiang Tan, Shrewsbury, MA (US); Cary D. Cottrell, Olympia, WA (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/404,975

(22) Filed: Mar. 31, 2003

(51) Int. Cl. H05K 7/02

(52) U.S. Cl. 361/748

(57) ABSTRACT

An electronic system includes a system board, a connector mounted on the system board, an electronic card attached to the connector, the card overhanging the connector at least on an inward end of the card, and a guide secured to the system board and spaced from the connector, wherein the guide is adapted to inhibit lateral movement of the card.

The invention relates to electronic systems, and more particularly to novel connectors and retention mechanisms for add-in cards.

### BACKGROUND AND RELATED ART

Many electronic systems provide the capability to supplement the functionality of the system by providing an interface through which additional electronic circuitry can be added to the system. For example, with reference to FIG. 1, a typical computer system 10 provides several connector slots 11 which are adapted to accept add-in cards 12. The add-in cards 12 may be retained by the mechanical forces between the connector 11 on the system board 13 and the card edge connector 14 on the add-in card 12. In many cases a bracket 15 is provided on the add-in card 14 which is secured to the chassis of the system at one end with a screw.

Some memory devices, which are relatively small, include latches on both ends of the memory connector. The latches help retain the memory card in the slot and may also be used to eject the memory card.

The power consumption and complexity of computer add-in cards has been increasing due to performance demands. For example, conventional high performance video cards may require power of about 25 watts and may weigh about 300 grams. As the required power increases, the weight of the add-in card consequently increases due to the need for more complex thermal solutions including larger heat sinks and fans. Even without increased power demands, the mass of the add-in card may increase due to larger card size and more devices and/or components on the add-in card.

If an add-in card is not sufficiently retained, the card can be displaced, or even popped off from the system board connector, e.g. due to shock and vibration, resulting in an open circuit, or even structure damage. The severity of the problem mainly depends on the card mass, the location of the center of gravity, and the card and connector design. Heavier add-in cards have more inertia during shock and/or vibration events. The increased card inertia applies a larger impact force on constraining parts of the card such as the card connector, thus potentially causing failures such as the connector housing pulling off from soldered pins and/or other damage on the connector housing itself.

### BRIEF DESCRIPTION OF THE DRAWINGS

Various features of the invention will be apparent from the following description of preferred embodiments as illustrated in the accompanying drawings, in which like reference numerals generally refer to the same parts throughout the drawings. The drawings are not necessarily to scale, the emphasis instead being placed upon illustrating the principles of the invention.

FIG. 1 is a perspective view of a conventional electronic system.

FIG. 2 is a schematic view of a conventional system subject to a lateral force.

FIG. 3 is a top, schematic view of an electronic system according to some embodiments of the invention.

FIG. 4 is a side, schematic view of the electronic system of FIG. 3.

FIG. 5 is a schematic view of another electronic system according to some embodiments of the invention.

FIG. 6 is a schematic view of another electronic system according to some embodiments of the invention.

FIG. 7 is a perspective view of a retention mechanism according to some embodiments of the invention.

FIG. 8 is a fragmented, perspective view of an electronic system including the retention mechanism of FIG. 7.

FIG. 9 is another perspective view of the retention mechanism of FIG. 7 from a reverse angle.

FIG. 10 is a fragmented, perspective view of an electronic system including the retention mechanism of FIG. 7 from the reverse angle.

FIG. 11 is a perspective view of another retention mechanism according to some embodiments of the invention.

FIG. 12 is another perspective view of the retention mechanism of FIG. 11 from another angle.

FIG. 13 is an exploded perspective view of an electronic system including the retention mechanism of FIG. 11.

FIG. 14 is an enlarged view of a mounting hole suitable for use with some embodiments of the invention.

FIG. 15 is a perspective view of another retention mechanism according to some embodiments of the invention.

FIG. 16 is an exploded, perspective view of the retention mechanism of FIG. 15.

FIG. 17 is another exploded, perspective view of the retention mechanism of FIG. 15 from another angle.

FIG. 18 is a fragmented, perspective view of an electronic system including the retention mechanism of FIG. 15.

FIG. 19 is a perspective view of another retention mechanism according to some embodiments of the invention.

FIG. 20 is a fragmented, perspective view of an electronic system including the retention mechanism of FIG. 19.

FIG. 21 is a perspective view of an electronic system including a connector with an integral retention mechanism according to some embodiments of the invention.

FIG. 22 is another perspective view of the electronic system of FIG. 21 from a reverse angle.

FIG. 23 is a schematic view of mounting pins according to some embodiments of the invention.

FIG. 24 is a schematic view of other mounting pins according to some embodiments of the invention.

FIG. 25 is a perspective view of a stiffening bracket according to some embodiments of the invention.

FIG. 26 is a fragmented, perspective view of an electronic system including a stiffening bracket according to some embodiments of the invention.

FIG. 27 is a fragmented, perspective view of another electronic system including a stiffening bracket according to some embodiments of the invention.

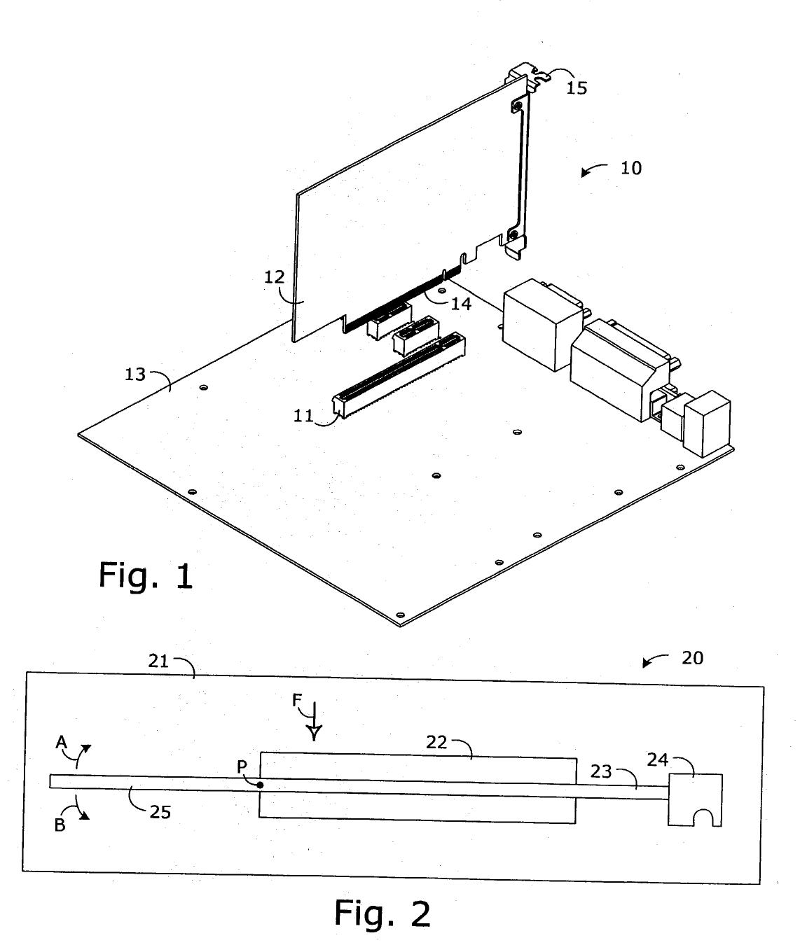

### DESCRIPTION

In the following description, for purposes of explanation and not limitation, specific details are set forth such as particular structures, architectures, interfaces, techniques, etc. in order to provide a thorough understanding of the various aspects of the invention. However, it will be apparent to those skilled in the art having the benefit of the present disclosure that the various aspects of the invention may be practiced in other examples that depart from these specific details. In certain instances, descriptions of well known devices, circuits, and methods are omitted so as not to obscure the description of the present invention with unnecessary detail.

As noted above, conventional high performance graphics cards may weigh about 300 grams. An add-in graphics card supporting the AGP standard may include a tab near the end of the connector to aid in retention of the card when the card is subject to vertical displacement forces. One problem with this tab is that to remove the card, the retention mechanism which engages with the tab must be manually disengaged. A further problem is that the supplemented retention is primarily in the vertical direction.

The inventors have discovered that with heavier add-in cards (e.g. 350 grams or more), lateral forces on the card can unseat the card and/or cause damage to the system. For example, lateral forces (i.e. forces including a component which is transverse to the plane of the add-in card) may be generated when the electronic system is subject to an impact which is perpendicular to the orientation of the add-in card. With reference to FIG. 2, an electronic system 20 includes a system board 21 with a connector 22 mounted on the system board 21. An add-in card 23 is attached to the connector 22 and overhangs the connector 22 on both ends. The add-in card 23 may include a bracket 24 on one end which may be attached to a chassis of the system 20. When a lateral force F is applied to the card 23, an end 25 of the card (opposite of the bracketed end) may flex, as indicated by the curved arrows A and B. Under lateral forces, a point P near the end of the connector 22 essentially becomes a pivot point about which the flexible material of the card 23 can bend. With a sufficiently heavy card subject to a sufficiently heavy lateral force, the flexing end 25 of the card can torque the card out of the connector and/or cause damage to the card and/or system.

The inventors have performed extensive tests for heavier cards in a computer system to confirm that card retention failure during shock and vibration conditions may occur due to impacts made perpendicular to the card. Even advanced graphics card with the additional retention tab failed the tests. It is believed that the supplemental retention tab has limited effect on restricting card deflection during side impact and therefore is not satisfactory to solve the side impact failures. In some instances (e.g. with a 400 gram graphics card), the additional retention tab was broken during shock testing.

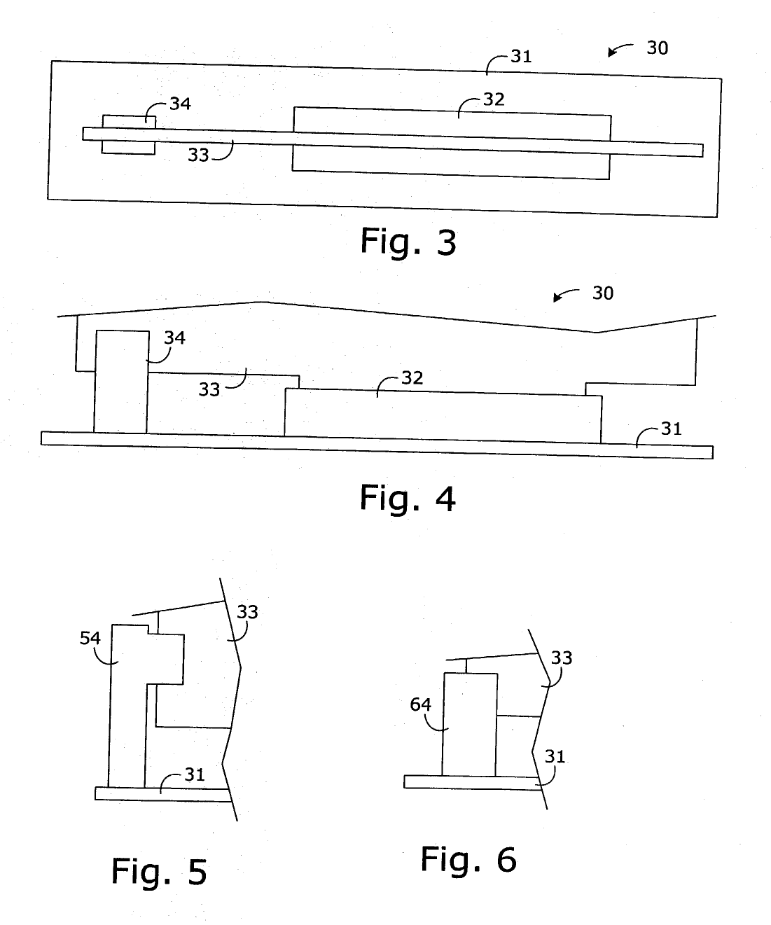

With reference to FIGS. 3 and 4, an electronic system 30 according to some embodiments of the invention includes a system board 31 and a connector 32 mounted on the system board 31. An electronic card 33 is attached to the connector and overhangs the connector 32 (e.g. at least on an inward end of the card 33 with respect to an outer wall of the system chassis). The system 30 further includes a guide 34 secured to the system board and spaced from the connector 32, where the guide 34 is adapted to inhibit lateral movement of the card 33. For example, the guide 34 contacts one or more side surfaces of the card 33 to reduce the amount the card 33 may flex about the pivot point near the end of the connector 32. Preferably, the guide 34 is adapted to provide a side constraint which substantially prevents lateral flexing of the card 33 at the point where the guide 34 contacts the card 33.

As illustrated in FIGS. 3 and 4, the guide 34 contacts the card 33 along a bottom edge of the card 33. Alternatively, a guide may be provided that contacts the card in any location on the card which is farther out from the pivot point. With reference to FIG. 5, a guide 54 contacts the card 33 along a back edge of the card 33. With reference to FIG. 6, a guide 64 contacts the card 33 along both the bottom and back edges of the card 33, at a corner of the card 33. Although less preferred, suitable guides may be provided which contact the card along a top edge or at some interior portion of the card. By providing a guide contact point which is farther out than the pivot point, the pivot point is moved to a location which allows less flexing and is therefore more likely to successfully retain the card.

An appropriate guide for a particular electronic system may take any suitable form and may be made from any suitable material. Plastic is a preferred material for the guide. Preferably, the guide provides a slot or channel that is a close fit with the thickness of the add-in card. For example, the guide may define a slot between two resilient protrusions. The width of the slot may be less than the thickness of the card, with the protrusions being sufficiently resilient to expand to accept the card. An advantage of the resilient protrusions is that they provide retention forces in the both the vertical and lateral directions, thus reducing the need for supplemental vertical retention mechanisms like the retention tab found on some advanced graphics cards. The guide may include alignment features to aid in the positioning of the slot with respect to the connector.

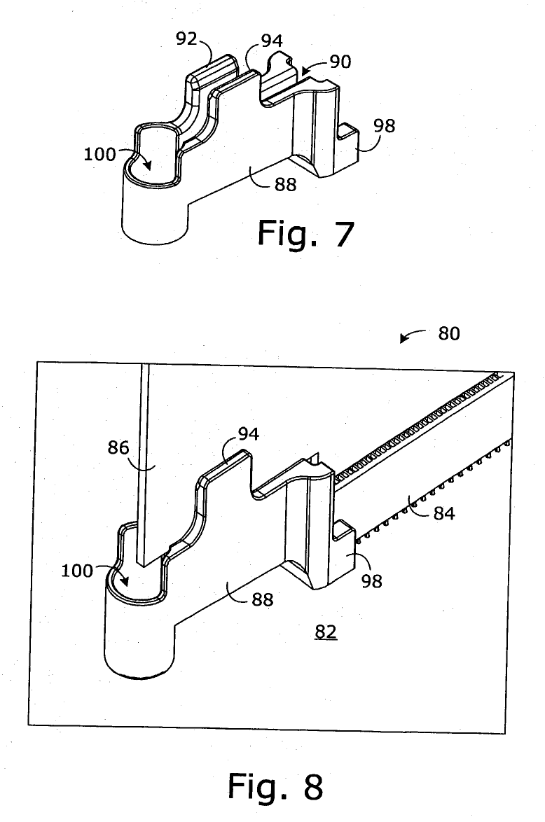

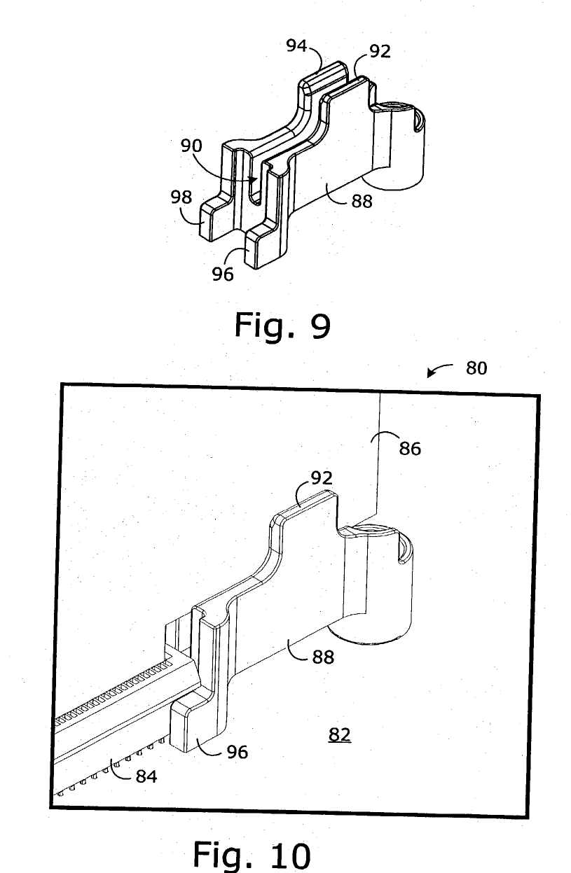

With reference to FIGS. 7-10, an electronic system 80 includes a system board 82 with a connector 84 mounted on the system board 82. An add-in card 86 is attached to the connector 84, with at least an inward end of the card 86 overhanging the connector 84. A guide 88 is secured to the system board 82 and contacts the card 86 on both sides of the card 86 at a point spaced from the connector 84. Accordingly, the guide 88 inhibits lateral movement of the card 86.

In the example of FIGS. 7-10, the guide 88 defines an elongated slot or rail 90 which extends from the end of the connector 84 for greater than a majority of the length of the card overhang. The guide 88 further includes two tabs 92 and 94 which extend vertically along the sides of the card 86 to raise the contact point. A higher contact point provides potentially greater stability. The tabs 92 and 94 are resilient and provide some inward bias to aid in retention of the card in the vertical direction. However, the card may be readily removed under manual force. In other words, there is no positive locking mechanism that must be disengaged before removing the card. This provides an advantage over some card retention systems that provide vertical retention mechanism near the connector that must be disengaged before the card is released.

The guide 88 also includes two arms 96 and 98 as an alignment feature. The arms 96 and 98 are adapted to mate with an outer surface of the connector 84. Advantageously, the arms 96 and 98 provide correct positioning of the rail 90 with respect to the connector 84.

To secure the guide 88 to the system board 82, the guide defines an opening 100 adapted to receive a fastener (e.g. a screw). The system board 82 provides a corresponding mounting hole (not shown). In some embodiments, the system board 82 corresponds to an ATX compatible motherboard. An advantage of the example of FIGS. 7-10 (and some other embodiments) is that the guide 88 may be secured to an ATX mounting hole already provided on the motherboard, thus reducing the amount of rework or board re-routing required to utilize the guide 88.

An unpackaged shock and vibration test was performed on an electronic system utilizing the example guide 88 for retention of an add-in card having a mass of about 450 grams. The center of gravity of the card was about 60 mm above the edge fingers and 100 mm from the card bracket. The card was successfully retained and passed the shock and vibration test.

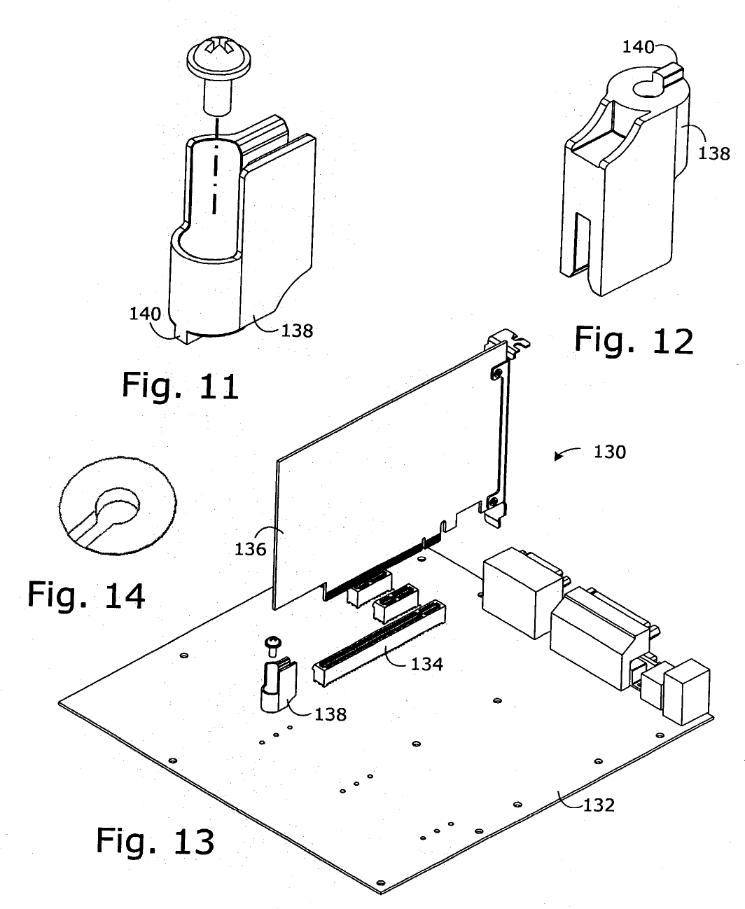

With reference to FIGS. 11-14, an electronic system 130 includes a system board 132 with a connector 134 mounted on the system board 132. An add-in card 136 is attached to the connector 134, with at least an inward end of the card 136 overhanging the connector 134. A guide 138 is secured to the system board 132 and contacts the card 136 on both sides of the card 136 at a point spaced from the connector 134. Accordingly, the guide 138 inhibits lateral movement of the card 136.

As compared to the guide 88, the guide 138 occupies less board space. The guide 138 includes a keying feature 140 adapted to mate with a key-hole shaped mounting hole (see FIG. 14). For example, an ATX mounting hole may be modified into a key-hole shape. This keying feature allows a much smaller size for the retention rail, in comparison to the guide 88, which uses the connector for alignment.

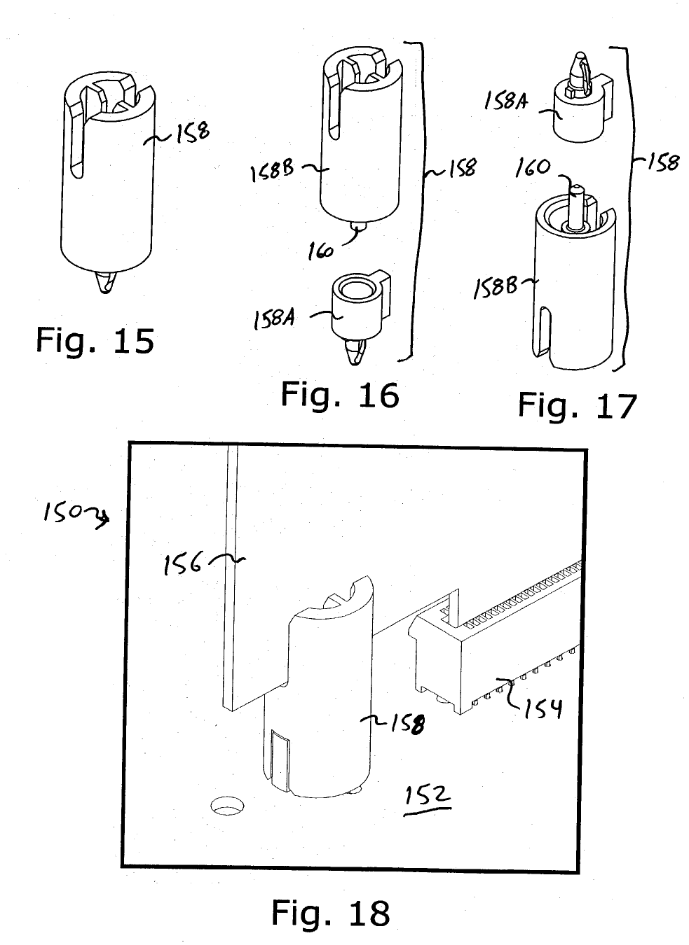

With reference to FIGS. 15-18, an electronic system 150 includes a system board 152 with a connector 154 mounted on the system board 152. An add-in card 156 is attached to the connector 154, with at least an inward end of the card 156 overhanging the connector 154. A guide 158 is secured to the system board 152 and contacts the card 156 on both sides of the card 156 at a point spaced from the connector 154. Accordingly, the guide 158 inhibits lateral movement of the card 156.

To further reduce the size of the guide 158, a push-pin mount structure is shown in FIGS. 15-19. The guide 158 uses a side constraint to retain the card, but with only one push-pin to mount to the system board 152. For example, the guide 158 may be constructed from two pieces 158A and 158B. The bottom piece 158A is inserted into a key-hole on the system board 152 and the top piece 158B with a push-pin 160 is then inserted into the bottom piece 158A, creating the mechanical pressure to attach the guide 158 to the system board 152. The keying features ensure correct alignment. This example has some advantages. First, it offers great flexibility. For example, a motherboard vendor does not have to install this guide in the first instance, giving a downstream system manufacturer the flexibility to install it on an as-needed basis. Second, it is extremely compact—the diameter of the guide may be only 2-3 mm in diameter.

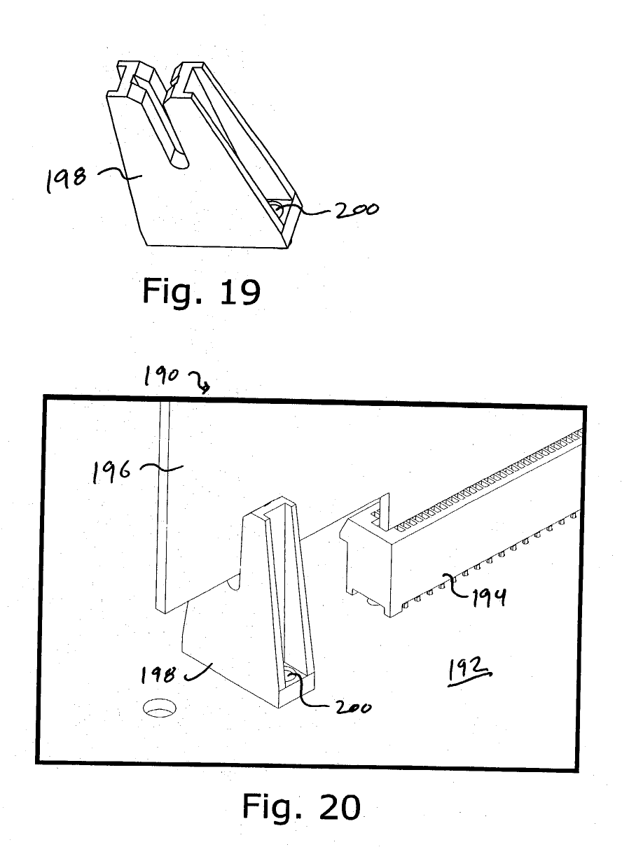

With reference to FIGS. 19-20, an electronic system 190 includes a system board 192 with a connector 194 mounted on the system board 192. An add-in card 196 is attached to the connector 194, with at least an inward end of the card 196 overhanging the connector 194. A guide 198 is secured to the system board 192 and contacts the card 196 on both sides of the card 196 at a point spaced from the connector 194. Accordingly, the guide 198 inhibits lateral movement of the card 196.

The guide 198 defines a plurality (i.e. at least two) holes 200 which are used as alignment features. Corresponding mounting holes are provided on the system board. The mounting holes are configured such that when the holes 200 are aligned with the mounting holes, the slot defined by the guide 198 is aligned with the connector 194. For example, the guide 198 may be mounted on the motherboard via two wave-soldered through-hole pins. Other methods of board mounting can also be used such as press-fit, or the addition of snap-in features. Many variations of the guide 198 and mounting fasteners are possible. In one example, a cut-out can be made for the guide 198 on the region between the two pins. The cut-out region can be used for IPAK components and routing on board, thus reducing impact of the placement the guide 198 on board layout. The key advantages of this example are its flexibility, independence of form factors, and compactness.

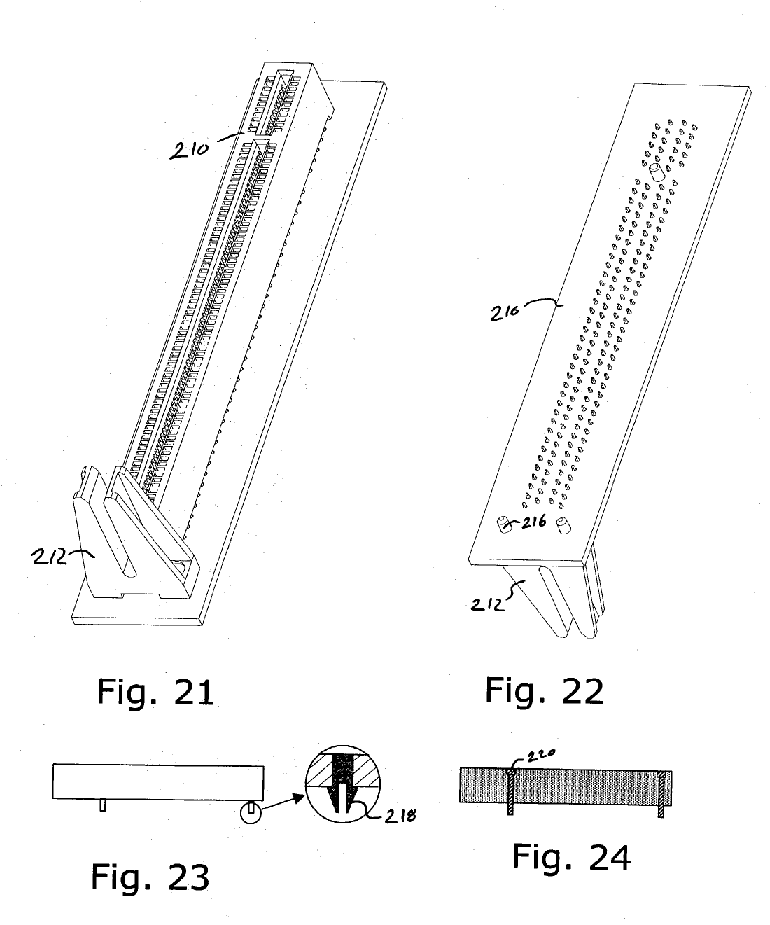

With reference to FIGS. 21-24, a connector 210 includes an integrated retention guide 212. Advantageously, the part count for assembly is reduced. In some embodiments, the length of the guide 212 may be vertically extended. In some embodiments, the connector pin connections to the motherboard may be strengthened by one of (or a combination of): widening of the base of the end of the connector; adding additional position pins 216; and/or using forklocks 218 for the position pins; and/or utilizing wave solder pins 220 instead of plastic pins. The extension of the guide will increase the side constraint during a shock event, reducing impact force on the connector. This reduced force, coupled with the strengthening of the connector pins is believed to reduce connector failures during shock and vibration.

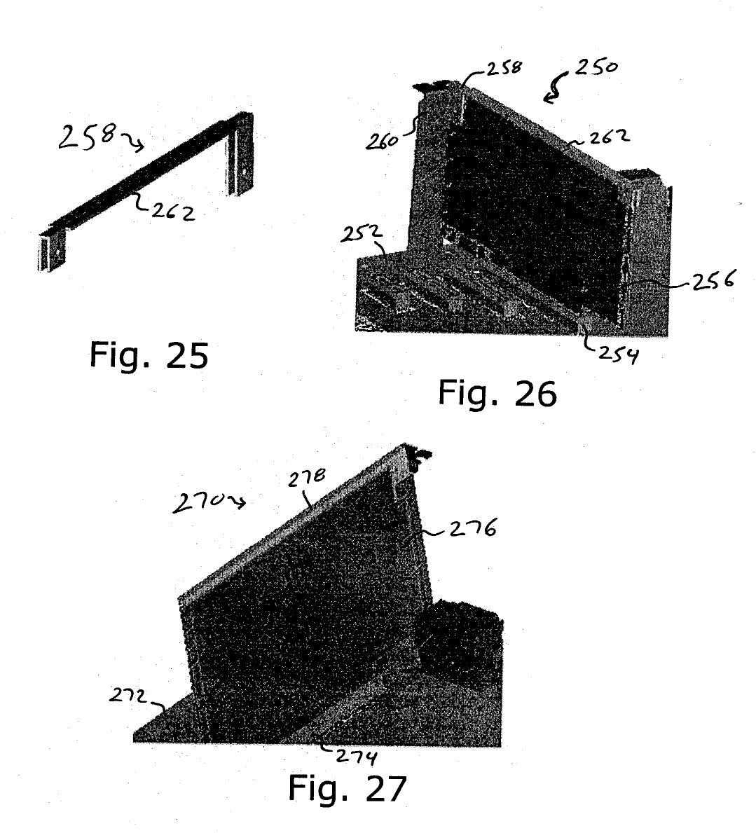

With reference to FIGS. 25-26, an electronic system 250 includes a system board 252 with a connector 254 mounted on the system board 252. An add-in card 256 is attached to the connector 254. The add-in card 256 includes a guide 258 disposed along a top edge of the card 256. The guide 258 is adapted to inhibit lateral movement of the card 256. For example, the guide 258 provides stiffening to the add-in card 256. The card may be optionally secured to a bracket 260 attached to a front edge of the card 256 or may be integrated with the bracket 260. For example, the guide 258 acts as a stiffening rib to the card 256 and reduces lateral deflection of the card 256 caused by an impact made perpendicular to the card 256. Constrained side deflection reduces impact force on the connector and thus reduces connector failures during shock and vibration. Advantageously, because the guide 258 is disposed along the top edge of the card 256, the guide 258 has no impact on the system board 252 layout or component placement.

In some embodiments, the guide 258 includes a flat strip 262 which does not contact at least one side of the card 256. For example, a card may define a keep-out zone for the bracket 260. The guide 258 may have a middle section of a flat strip with no coverage on the card surface (see FIG. 26). Only a small additional keep-out zone may be needed at the top end of the card opposite of the bracket end.

With reference to FIG. 27, an electronic system 270 includes a system board 272 with a connector 274 mounted on the system board 272. An add-in card 276 is attached to the connector 274. The add-in card 276 includes a guide 278 disposed along a top edge of the card 276. The guide 278 is adapted to inhibit lateral movement of the card 276. For example, the guide 278 provides stiffening to the add-in card 276. The card may be optionally secured to a bracket attached to a front edge of the card 276 or may be integrated with the bracket. For example, the guide 278 acts as a stiffening rib to the card 276 and reduces lateral deflection of the card 276 caused by an impact made perpendicular to the card 276. Constrained side deflection reduces impact force on the connector and thus reduces connector failures during shock and vibration. Advantageously, because the guide 278 is disposed along the top edge of the card 276, the guide 278 has no impact on the system board 272 layout or component placement. In this example, the guide defines a channel or rail which contacts both sides of the card 276 along substantially the entire top edge of the card 276.

The foregoing and other aspects of the invention are achieved individually and in combination. The invention should not be construed as requiring two or more of the such aspects unless expressly required by a particular claim. Moreover, while the invention has been described in connection with what is presently considered to be the preferred examples, it is to be understood that the invention is not limited to the disclosed examples, but on the contrary, is intended to cover various modifications and equivalent arrangements included within the spirit and the scope of the invention.

What is claimed is:

1. An electronic system, comprising:
a system board;
a connector mounted on the system board;
an electronic card attached to the connector, the card overhanging the connector at least on an inward end of the card; and
a guide secured to the system board and spaced from the connector, wherein the guide is adapted to inhibit lateral movement of the card.

2. The system of claim 1, wherein the guide is adapted to provide a side constraint which substantially prevents lateral flexing of the card at a point where the guide contacts the card.

3. The system of claim 1, wherein the guide contacts one or more side surfaces of the card.

4. The system of claim 3, wherein the guide contacts two opposed side surfaces of the card.

5. The system of claim 1, wherein the guide is positioned along a bottom edge of the card.

6. The system of claim 1, wherein the guide is positioned along a back edge of the card.

7. The system of claim 1, wherein the guide is position along a top edge of the card.

8. The system of claim 1, wherein the guide is positioned at a corner of the card.

9. The system of claim 1, wherein the guide includes an alignment feature adapted to align the guide with the connector.

10. The system of claim 9, wherein the alignment feature includes arms adapted to mate with the connector.

11. The system of claim 9, wherein the alignment feature includes a keying feature.

12. A method, comprising:
providing a system board;
mounting a connector on the system board;
attaching an electronic card to the connector, the card overhanging the connector at least on an inward end of the card; and
securing a guide to the system board spaced from the connector; and
inhibiting lateral movement of the card with the guide.

13. The method of claim 12, wherein inhibiting lateral movement of the card comprises providing a side constraint with the guide which substantially prevents lateral flexing of the card at a point where the guide contacts the card.

14. The method of claim 12, wherein inhibiting lateral movement of the card comprises contacting one or more side surfaces of the card with the guide.

15. The method of claim 14, wherein the guide contacts two opposed side surfaces of the card.

16. The method of claim 12, wherein securing the guide comprises positioning the guide along a bottom edge of the card.

17. The method of claim 12, wherein securing the guide comprises positioning the guide along a back edge of the card.

18. The method of claim 12, wherein securing the guide comprises positioning the guide along a top edge of the card.

19. The method of claim 12, wherein securing the guide comprises positioning the guide at a corner of the card.

20. The method of claim 12, further comprising providing the guide with an alignment feature adapted to align the guide with the connector.

21. The method of claim 20, wherein the alignment feature includes arms adapted to mate with the connector.

22. The method of claim 20, wherein the alignment feature includes a keying feature.
